(19) United States
(12) Patent Application Publication
(10) Pub. No.: US 2004/0069638 A1
(43) Pub. Date: Apr. 15, 2004

(54) Electrophoretic/electrochemical devices with nanometer-scale metallic components

(75) Inventors: Michael P. Surh, Livermore, CA (US); William D. Wilson, Pleasanton, CA (US); Troy W. Barbee JR., Palo Alto, CA (US); Stephen M. Lane, Oakland, CA (US)

Correspondence Address: Alan H. Thompson, Assistant Laboratory Counsel, Lawrence Livermore National Laboratory, P.O. Box 808, L-703, Livermore, CA, 94551, US

(73) Assignee: The Regents of the University of California

(21) Appl. No.: 10/262,510

(22) Filed: Sep. 30, 2002

(51) Int. Cl. G01R 1/00

(52) U.S. Cl. 204/600

(57) ABSTRACT

Electrophoric/electrochemical devices involving two separate, parallel, flat surfaces consisting of metal/insulator nano-laminates. The use of two nano-laminates increases the electrophoretic flow through a channel of given dimensions at a given applied voltage as compared to prior approaches. The introduction of these separate electrodes to the walls of the fluid channel maximizes the amount of exposed metal and minimizes the diffusion distance to facilitate electrochemical redox reactions. The combination of rapid solvent turnover and efficient detection of low concentrations of analyte creates a fast and sensitive detector.

The United States Government has rights in this invention pursuant to Contract No. W-7405-ENG-48 between the United States Department of Energy and the University of California for the operation of Lawrence Livermore National Laboratory.

### BACKGROUND OF THE INVENTION

The present invention relates to sensors, particularly to sensors using nano-laminates, and more particularly to improved sensor devices defined by two separate, parallel, flat surfaces consisting of metal/insulator nano-laminates and to stacks of these metal/insulator nano-laminates, for use in microfluidic devices.

The ability to collect and organize atoms, molecules, nanocrystals, colloids, cells, proteins, and spores on a substrate is a major goal of nano science and technology and has enormous potential in the fields of material science, synthetic chemistry, biology and medicine, as well as national security. There has been a problem in developing a technology in which the structural scale of a template can be engineered by man to match the scale of a nano body and thereby manipulate it to form an ordered structure or to selectively absorb the nano body enabling assay and analysis. This has been addressed using standard lithographic approaches in the past that cannot, at this time, achieve nano dimensions over significant areas in the range less than 70 nm.

The present invention involves electrophoretic/electrochemical devices with nanometer-scale metallic components. This invention is an improvement over the prior known electrophoretic fluid transport channels using a layered composite material formed as nano-laminate by magnetron sputtering of material, such as silica and alumina, on a substrate which is sectioned and polished to expose a nano-laminate surface as a sensor. Thus, prior nano-laminate devices are exemplified by the sensor template described on claimed in copending U.S. application Ser. No. 10/167,926 filed Jun. 11, 2002, and assigned to the same assignee. The present invention is an improvement over the prior nano-laminate approach referenced above and comprises a device defined by two separate, parallel, flat surfaces consisting of metal/insulation nano-laminates, which can also be positioned along a length of a fluid channel.

### SUMMARY OF THE INVENTION

It is an object of the present invention to provide an improved microfluidic device consisting of metal/insulator nano-laminates.

Another object of the invention is to provide a metal/insulator nano-laminate device which increases the electrophoretic flow through a channel of given dimensions at a given applied voltage.

Another object of the invention is to provide an improved metal/insulator nano-laminate for an electrophoretic fluid transport channel.

Another object of the invention is to provide a metal/insulator nano-laminate defined by two separate, parallel, flat surfaces consisting of metal/insulator nano-laminates.

Another object of the invention is to provide one or more metal/insulator nano-laminates for use in a microfluidic device.

Other objects and advantages will become apparent from the following description and accompanying drawings. The invention involves nano-scale metallic components for electrophoretic/electrochemical devices. More specifically, the invention involves an improved device defined by two separate, parallel, flat surfaces consisting of a metal/insulator nano-laminate. The use of the two nano-laminates increase the electrophoretic flow through a channel of given dimensions at a given applied voltage. The flow field also approaches plug flow, unlike in the prior approach. The introduction of these separate electrodes to the walls of the fluid channel maximizes the amount of exposed metal and minimizes the diffusion distance to facilitate electrochemical redox reactions. The combination of rapid solvent turnover and efficient detections of low concentrates of analyte creates a fast and sensitive detector. This nano-scale metallic component can be incorporated in a microfluidic device for the purpose of processing, separating, or performing a chemical or biological assay or analysis on molecules of colloidal particles in a very small fluid sample. Such devices can be used as detectors of pathogens or other trace analytes.

### BRIEF DESCRIPTION OF THE DRAWINGS

The accompanying drawings, which are incorporated into and form a part of the disclosure, illustrate embodiments of the invention and, together with the description, serve to explain the principles of the invention.

FIGS. 1A and 1B illustrate embodiments of the nanometer scale metallic components of the invention, with the direction of fluid flow therethrough being shown by arrows.

FIG. 2 illustrates an embodiment similar to FIG. 1B located in an electrophoretic fluid channel, with the two adjacent walls of the metal/insulator composite simultaneously functioning as electrodes in an electrochemical circuit.

### DETAILED DESCRIPTION OF THE INVENTION

The present invention relates to metal/insulator nano-laminates components for electrophoretic/electrochemical devices. The present invention is an improvement over the above-referenced prior approach involving a layered metal/insulator composite (nano-laminate) material. The improved device of the present invention involves two separate, parallel, flat surfaces, each consisting of metal/insulator nano-laminates and which are mounted in a spaced relation in a fluid transport channel. The use of two nano-laminates, instead of the previous single nano-laminate, increases the electrophoretic flow through a channel of given dimensions at a given applied voltage compared to the prior single nano-laminate approach.

The flow field also approaches plug flow, unlike the prior single nano-laminate approach. The introduction of these separate electrodes to the walls of the fluid channel maximizes the amount of exposed metal and minimizes the diffusion distance to facilitate electrochemical redox reactions. The combination of rapid solvent turnover and efficient detection of low concentrations of analyte creates a fast and sensitive detector.

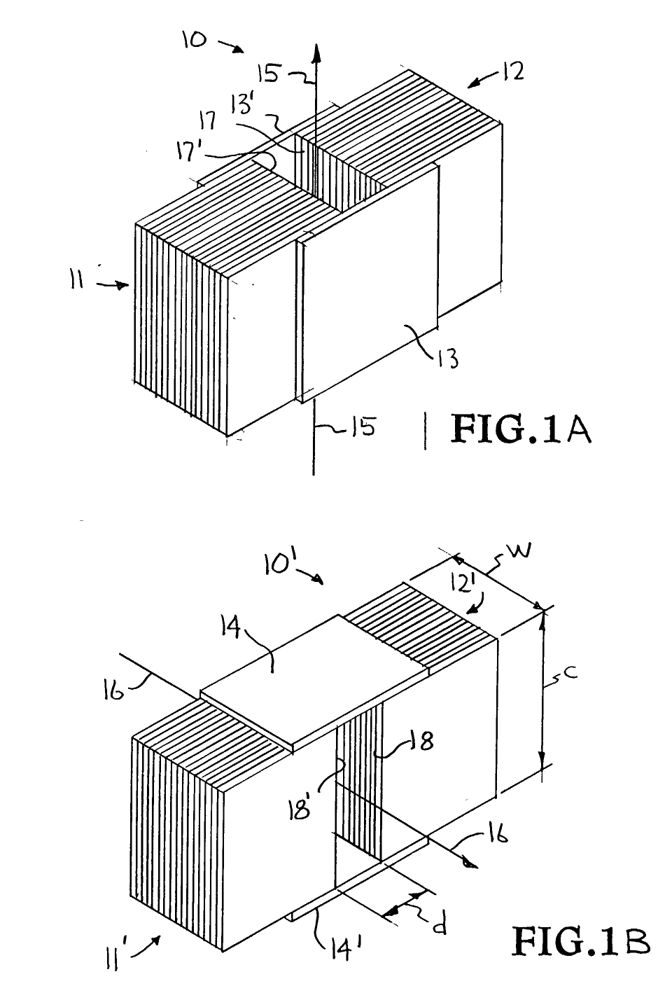

The nano-laminate electrophoretic device of the above-referenced copending application uses only one exposed surface of the channel to induce fluid flow, relying on the electrical isolation of successive metallic layers. The opposite, parallel surface of that prior device is insulating and makes no contribution to the driving electric field. The nano-laminate components illustrated in FIGS. 1A and 1B display an improvement over the devices of the above-referenced copending application in that two surfaces of the components are exposed to the fluid channel and can drive electrophoretic flow together when the same voltage is applied to each element. If desired, a number of the nano-laminates can be positioned in spaced relation along a length of a fluid channel.

As shown in FIGS. 1A and 1B, fluid channel components indicated generally at 10 and 10′ comprises two separate, parallel, flat surfaces consisting of metal/insulator nano-laminated components generally indicated at 11, 12 and 11′, 12′. The nano-laminate components 11, 12 and 11′, 12′ are held at a fixed separation, d, see FIG. 1B, which defines the fluid channel width, by segments of insulating adhesive material indicated at 13-13′ and 14-14′, respectively. The adhesive material segments also define two of the four walls of a fluid channel indicated by arrows 15 and 16, respectively, through which fluid flows. Electric fields along the direction of arrows 15 and 16 must be established by means known in the art on both of the exposed nano-laminate surfaces indicated at 17-17′ and 18-18′.

By way of example, each of the nano-laminated components 11, 12 and 11′ 12′ may be composed of from two pair to an arbitrary number of multilayers, each composed of alternating layers of metal, such as aluminum, gold, and molybdenum, and layers of insulation, such as alumina, silica, and ceria, with layer thicknesses in the range of nm to μm.

The insulating adhesive material may be composed of epoxy with a thickness of μm to nm. The components 11, 12 and 11′, 12′ have a width w of μm to millimeters, height c of millimeters to 10's of centimeters and are separated by the distance d of microns (the fluid channel dimension). The overall width of components 11, 12 and 11′, 12′ of FIGS. 1A and 1B may be millimeters to centimeters which includes the separation distance d. The components 11, 12 and 11′, 12′ may be composed of metal/insulator pairs in the range of 2 to 10⁶.

When the fluid channel dimension (distance d) are such that d<<c, the flow profile across the fluid channel will approach plug flow. If desired, the electric fields across the two adjacent exposed nano-laminate surfaces can, instead, be of different magnitudes or even opposite directions to maximize the shear flow in the fluid channel and facilitate mixing of the enclosed fluid.

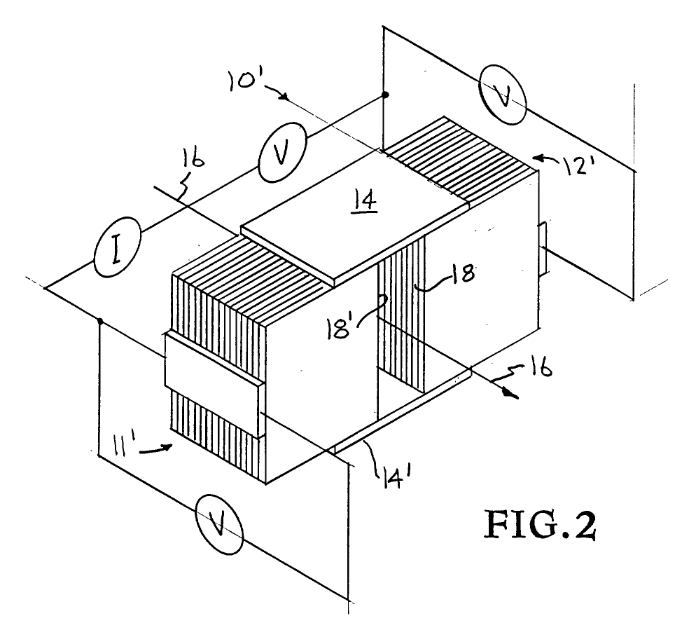

The separate metal/insulator components 11, 12 or 11′ 12′ can also function as two electrodes. This makes cyclic voltammetry possible, employing an electrochemical redox cycle for detection or characterization of an analyte molecule or particle (see FIG. 2). The ability to incorporate these metallic elements along the entire electrophoretic channel increases the electrode surface area to fluid volume ratio and increases the sensitivity of the device to low concentrations of analyte. The steady fluid flow within the fluid channel ensures thorough flushing and sample replacement within the entire sample volume in order to make rapid measurements.

FIG. 2 illustrates an embodiment like that of FIG. 1B and corresponding reference numerals indicate corresponding components, and shows an electrophoretic fluid channel driven with voltage V. The two exposed walls 18 and 18′ of the metal/insulator components 12 and 12′ simultaneously function as electrodes in an electrochemical circuit (at relative voltage V′). The electrochemical circuit is closed by a redox cycle of the analyte between the two nano-laminate walls 18-18′ defining the fluid channel. Measurements of the current I as a function of voltage V′ provides standard electrochemical characterization of the material in the electrolyte (cyclic voltametric detection and characterization)

It has thus been shown that the present invention provides an improved sensor utilizing a pair of parallel, spaced, flat metal/insulator nano-laminates having exposed surfaces through which fluid to be processed passed. The use of two nano-laminate structures increase the electrophoretic flow through the channel, in which the structures are located, and of given dimensions at a given applied voltage as compared previous nano-laminate approaches using a single structure.

The improved nano-laminate component of this invention can be incorporated in a microfluidic device for the purpose of processing, separating, or performing a chemical or biological assay or analysis on molecules of colloidal particles in a very small fluid sample. Such devices can be used as detectors of pathogens or other trace analytes.

While particular embodiments have been illustrated or described, along with materials and parameters, to exemplify and teach the principles of the invention, such are not deemed to be limiting. Modifications and changes may become apparent to those skilled in the art, and it is intended that the invention be limited only by the scope of the appended claims.

What is claimed is:

1. In a sensor, the improvement comprising:
a nano-laminate component,
said nano-laminate component including a plurality of separated exposed cross-sections.

2. The improvement of claim 1, wherein said pair of separated exposed cross-sections are located in separate nano-laminate structures,
said structures being interconnected by an insulating material.

3. The improvement of claim 2, wherein said nano-laminate structures are separated by a distance d, and wherein said distance d defines a width of a fluid channel.

4. The improvement of claim 3, wherein said distance d is less than a height of said structures.

5. The improvement of claim 3, wherein said distance d is equal to or greater than a height of said structures.

6. The improvement of claim 2, wherein said structures comprise metal/insulator nano-laminates.

7. The improvement of claim 6, wherein said metal/insulator nano-laminates comprise combinations of layers of metal selected from the group consisting of Al, Au, and Mo, or any other metal from which nano-laminate structures may be formed; and layers of insulator material selected from the group consisting of Al₂O₃, SiO₂, and CeO₂, or any other insulator from which nanolaminates may be formed.

8. The improvement of claim 6, wherein said metal/insulator nano-laminate comprises pairs of metal/insulator layers in the range of two to millions of pairs.

9. The improvement of claim 1, wherein said plurality of separated exposed cross-sections are formed on a pair of nano-laminated metal/insulator structures.

10. The improvement of claim 9, wherein said structures a secured together in a spaced relation by insulating adhesive material.

11. The improvement of claim 10, wherein said structures are separated by a distance in the range of μm to millimeters.

12. The improvement of claim 11, wherein the distance is less than, equal to, or greater than a height of said structures.

13. In an electrophoretic/electrochemical device, the improvement comprising:
at least one nanometer-scale component,
said component including two separate, parallel, flat surfaces consisting of metal/insulator nano-laminates.

14. The improvement of claim 13, wherein said nano-laminates are secured in fixed separated relation by insulating adhesive material so as to define a fluid flow channel therebetween.

15. The improvement of claim 14, wherein said nano-laminates have walls which simultaneously function as electrodes in an electrochemical circuit.

16. The improvement of claim 14, wherein said insulating adhesive material defines in conjunction with wall surfaces of said nano-laminates four walls of a fluid channel.

17. The improvement of claim 13, wherein said nano-laminates are separated by a distance selected from the group consisting of less than a height of said nano-laminates and greater than the height of said nano-laminates.
